(19) United States
(12) Patent Application Publication
(10) Pub. No.: US 2008/0194054 A1
(43) Pub. Date: Aug. 14, 2008

(54) LED ARRAY PACKAGE STRUCTURE HAVING SILICON SUBSTRATE AND METHOD OF MAKING THE SAME

(76) Inventors: Hung-Yi Lin, Tao-Yuan Hsien (TW); Hong-Da Chang, Tai-Chung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/735,499

(22) Filed: Apr. 16, 2007

(30) Foreign Application Priority Data
Feb. 8, 2007 (TW) 096104582

(51) Int. Cl. H01L 21/00; H01L 33/00

(52) U.S. Cl. 438/64; 257/99; 257/E21.001; 257/E33.001

(57) ABSTRACT

An LED array package structure having a silicon substrate is disclosed. The LED array package structure comprises a silicon substrate having a plurality of cup-structures thereon, a reflective layer disposed on the silicon substrate, a transparent insulation layer disposed on the reflective layer, a conductive layer disposed on the transparent insulation layer and a plurality of LEDs disposed respectively on the conductive layer in each cup-structures.

### BACKGROUND OF THE INVENTION

1. Field of the Invention

The present invention relates to a light emitting diode (LED) array package and a method of making the same, and more particularly, to an LED array package having a silicon substrate with cup-structures and a method of making the same by utilizing a microelectromechanical process or semiconductor process.

2. Description of the Prior Art

Since the LED has advantages of a long lifetime, a small size, a high resistance to shock, a low heat emission, and a low consumption of electrical power, the LED is widely applied as a pilot lamp or a light source for various household appliances and instruments. Additionally, the LED has been developed toward producing colorful lights and high brightness in recent years, so that the LED is further applied in many kinds of movable or large-sized electronic products ranging from being a back light source of a display, lamp, traffic signals and outside colorful signboards to becoming a stream of illumination light sources with low power consumption and low contamination characteristics in the future.

Please refer to FIG. 1. FIG. 1 is a schematic diagram illustrating an LED array package structure according to the prior art. The LED array package structure 10 includes a flat substrate 20 and a plurality of LEDs 30 disposed on the substrate 20. The substrate 20 is a PCB or a lead frame. The LEDs 30 are arranged in an array. Because there is a distance between each LED 30 and the adjacent one, the light pattern of the LED array package structure 10 has dark regions. Although each LED 30 has the scattering sidelight emitted from the sides thereof, the LED array package structure 10 still has dark regions between the LEDs 30. Also, the assembly machine used for packaging has a limitation in precision of die attachment, so the distance 40 between the LEDs 30 is more than 100 μm. Therefore, if a uniformly mixing of light is required, a distance necessary to observe a uniformly mixed light is long. Further, the LED array package structure 10 cannot be applied to a product needing a light source with high resolution, such as liquid crystal display etc.

Recently, in order to reduce the scattering sidelight to improve the light pattern, it is a familiar method to use an LED having a large size substantially the same as the LED array or to use a cup-structure to improve light patterns. But, the machining method has a limitation so that the method of using the cup-structure cannot improve the assembly size in spite of having a function of condensing light. In addition, please refer to FIG. 2. FIG. 2 is a relationship diagram of the size vs. the proportion of the scattering sidelight to total illumination of an LED. As shown in FIG. 2, the brightness of the large-sized LED is higher than the small one, and the proportion of the scattering sidelight to total illumination of the large-sized LED is smaller than the small one. However, the illumination area of the large-sized LED is too large so that a part of the light will be totally reflected in the LED so as to reduce the illumination efficiency. Additionally, although a thin GaN technology used to make extremely thin sidewalls of an LED is a method utilized to reduce the light emitted from the side surfaces of the LED and to increase the light emitted from the top surface of the LED, the cost of the thin GaN technology is much more expensive than the ordinary technology.

Therefore, in order to achieve high brightness, to increase the light utility and to reduce the manufacturing cost of the package structure have become important subjects in the LED array package structure.

### SUMMARY OF THE INVENTION

It is therefore an object of the present invention to provide an LED array package structure having a silicon substrate and a method making the same so as to increase light utility and reduce the manufacturing cost.

According to an embodiment of the present invention, an LED array package structure having a silicon substrate is provided. The LED array package structure comprises a silicon substrate having a plurality of cup-structures thereon, a reflective layer disposed on the silicon substrate, a transparent insulating layer disposed on the reflective layer, a conductive layer disposed on the transparent insulating layer and a plurality of LEDs respectively disposed on the conductive layer in each cup-structure.

According to an embodiment of the present invention, a method of fabricating an LED array package structure having a silicon substrate is provided. First, a silicon substrate is provided, and an etching process is performed to form a plurality of cup-structures on the silicon substrate. Then, a reflective layer and a transparent insulating layer are respectively formed on the silicon substrate in turn, and a conductive layer is formed on the transparent insulating layer. Final, a plurality of LEDs is respectively bonded on the conductive layer in each cup-structure.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating an LED array package structure according to the prior art.

FIG. 2 is a diagram illustrating the relationship of the size vs. the proportion of the scattering sidelight to total illumination of an LED.

FIG. 3 is a cross-sectional schematic diagram illustrating an LED array package structure having a silicon substrate.

FIG. 4 is a diagram illustrating the relationship of the size vs. the fill factor of the LED array package structure without cup-structures.

FIG. 5 is a diagram illustrating the relationship of the size vs. the fill factor of the LED array package structure with cup-structures 300 μm in depth.

FIG. 6 to FIG. 9 are schematic diagrams illustrating a method of fabricating an LED array package structure according to a preferred embodiment of the present invention.

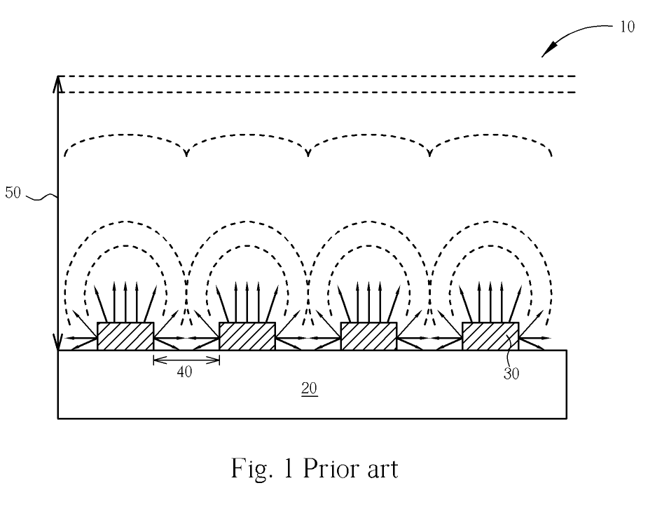

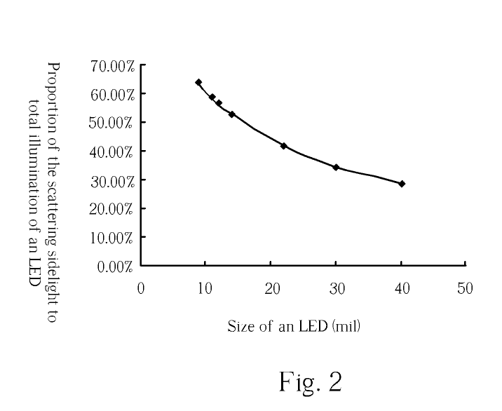

### DETAILED DESCRIPTION

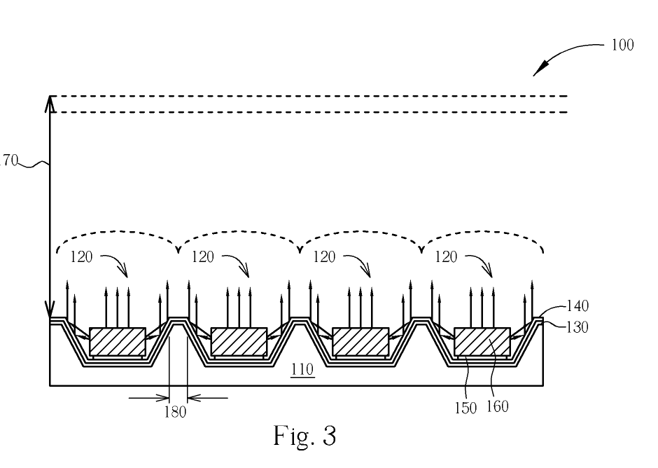

FIG. 3 is a cross-sectional schematic diagram of an LED array package structure having a silicon substrate. The LED array package structure 100 includes a silicon substrate 110 having a plurality cup-structures 120 thereon, a reflective layer 130 disposed on the silicon substrate 110 and covering the surface of each cup-structure 120, a transparent insulating layer 140 disposed on the reflective layer 130, a conductive layer 150 disposed on the transparent insulating layer 140 and a plurality of LEDs 160 respectively disposed on the transparent insulating layer 150 in each cup-structure 120, wherein each cup-structure 120 has inclined sidewalls, and the function of the sidewalls is used to reflect the scattering sidelight emitted from the side surfaces of the LEDs 160 and change the direction of the scattering sidelight to the upward direction. If a specific optical effect of the LED array package structure 100 is required, the effect can be achieved by adjusting depth, width, shape of sidewalls and an inclined angle of the sidewalls of the cup-structure 120. The top view of each cup-structure 120 can be rectangular or another geometric shape. In addition, the arrangement of the cup-structures 120 on the silicon substrate 110 can be one or two dimensional array, and the distance 180 between the edges of the adjacent cup-structures 120 is substantially less than 10 μm.

The material of the silicon substrate 110 includes polycrystalline silicon, amorphous silicon or monocrystalline silicon. Additionally, the silicon substrate 110 can be a rectangular silicon chip or a circular silicon chip, and the silicon substrate 110 can further include integrated circuits or passive components therein so as to form an illumination system with the LEDs 160. Besides, the silicon substrate 110 further includes a good thermal conductivity. While the LEDs 160 are emitting, heat will be generated in the LEDs 160. Because of the good thermal conductivity of the silicon substrate 110, the heat of the LEDs 160 can be quickly dissipated. However, the silicon substrate 110 is not a good reflective material, so a reflective layer is disposed on the silicon substrate 110 in order to let the cup-structures 120 have reflectivity. The sidewalls of the cup-structures 120 can reflect the scattering sidelight emitted from the sides of the LEDs 160 to let the scattering sidelight reflect upward. The reflective layer 130 is a good reflective material, such as metal or optical films. The conductive layer 150 is a medium for electrically connecting the LEDs 160 and the external circuits (not shown in figure). The conductive layer 150 is made of metal, and the conductive layer 150 can be used to connect each cup-structure 120 and each LED 160.

The LED 160 emits light from the top surface and the side surfaces thereof. In the prior art, the scattering sidelight cannot be used. The LED array package structure 100 of the present invention can use the scattering sidelight more efficiently with the cup-structures 120, because the cup-structures 120 can change the direction of the scattering sidelight to reflect upward. Therefore, the light emitting area of each LED 160 disposed in each cup-structure 120 can be similar to the opening of one cup-structure 120, not being the light emitting area of only one LED 160. Furthermore, the distance 180 between the edges of the adjacent cup-structures 120 is less than 10 μm so that the light emitted from the adjacent LEDs 160 can be mixed with each other. Because the light emitted from the top surface of the LEDs 160 all have a scattering angle, the light emitted from the top surface of the adjacent LEDs 160 can be mixed with each other, and a part of the scattering sidelight mixes too. And, because the scattering sidelight can be reflected upward, light pattern of the LED array package structure 100 is similar to a light pattern of a LED whose size is substantially the same as the area of the LED array package structure 100, and the uniform light-mixing distance can be shortened. The dark regions produced in the prior art can be avoided. In addition, the LED array package structure 100 can use a plurality of LEDs 160 with small area to be arranged together so as to be like a large LED. Therefore, the total illumination efficiency can be increased, and the cost can be reduced.

Additionally, the LED array package structure 100 of the present invention further has an advantage of a high fill factor. The definition of the fill factor is the proportion of the top surface area of the LEDs 160 to the top surface area of the silicon substrate 110. According to the limitation of the packaging machine in die attachment, the distance between the LEDs 160 is substantially more than 100 μm. Without having the cup-structures 120, and taking the LED that size is 600 μm as an example, the fill factor after packaging can be calculated. The fill factor is less than 75 percent. If a larger LED is taken as an example, the fill factor can be increased. However, the larger LED has a worse illumination efficiency. The difference between the fill factor of with the cup-structures and without the cup-structures is compared as follows.

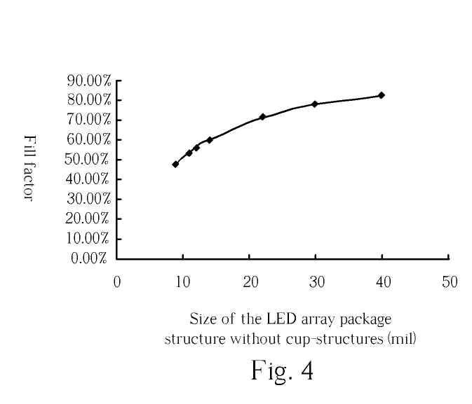

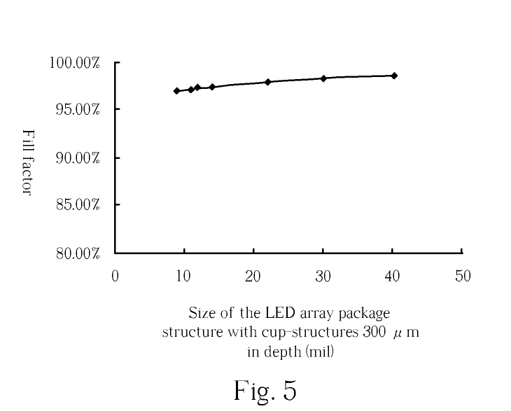

Please refer to FIG. 4 and FIG. 5. FIG. 4 is a relationship diagram of the size vs. the fill factor of the LED array package structure without the cup-structures. FIG. 5 is a relationship diagram of the size vs. the fill factor of the LED array package structure with the cup-structures 300 μm in depth. As shown in FIG. 4, taking the LED which size is 9 mil as an example, the fill factor is 47.93 percent without the cup-structures. In addition, as shown in FIG. 5, no matter how large the LED be, the fill factor with the cup-structures is higher than the fill factor without the cup-structures according to FIG. 4 and FIG. 5. The increase of the fill factor not only reduces the package size but also increases mixing of the light emitted from the adjacent LEDs so that the uniformity of the light pattern is increased. Therefore, because the LED array package structure has a silicon substrate having the cup-structures with high density and high fill factor in an array, the LED array package structure has characteristics of uniformly light pattern and a short light-mixing distance. Also, when the LED array package structure is applied to large-sized lighting, the cost can be reduced.

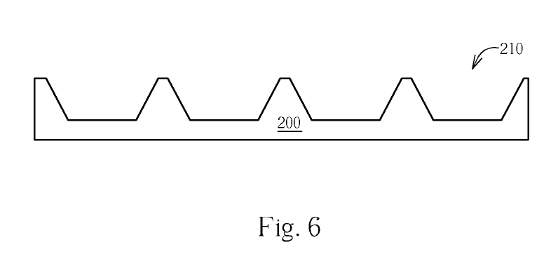

Please refer to FIG. 6 through FIG. 9. FIG. 6 to FIG. 9 are schematic diagrams illustrating a method of fabricating an LED array package structure according to a preferred embodiment of the present invention. As shown in FIG. 6, first, a silicon substrate 200 is provided, and a mask pattern is formed on the silicon substrate 200 by performing a lithographic process. The mask pattern (not shown in figure) includes a plurality of openings, and the distance between the adjacent openings is less than 10 μm. Next, an etching process is performed to form a plurality of cup-structures 210 with inclined sidewalls on the silicon substrate 200. The cup-structures 210 are defined by the openings. The etching process can be a dry etching process such as a reactive ion etching process (RIE) process or Bosch process or a wet etching process utilizing potassium hydroxide (KOH), tetramethyl ammonium hydroxide (TMAH) or ethylenediamine-pyrocatechol-water (EDP) solution as an etching solution. The etching process is utilized to etch the silicon substrate 200 to have the cup-structures 210 with the inclined sidewalls. The Bosch process, also known as pulsed or time-multiplexed etching, alternates repeatedly between standard isotropic plasma etch and deposition of a chemically inert passivation layer to achieve nearly vertical structures. The required optical effect of the LED array package structure can be achieved by controlling position, depth, width, shape of the sidewalls, inclined angle of the sidewalls and etc. of the cup-structures 210.

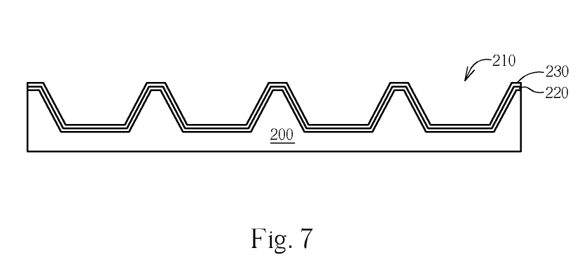

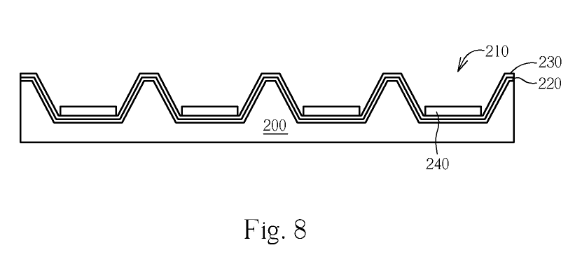

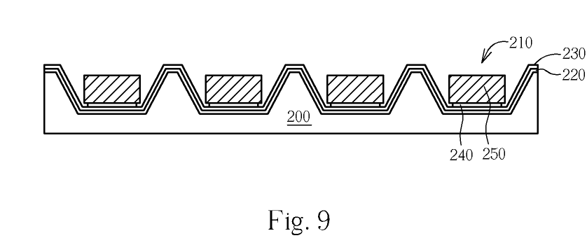

As shown in FIG. 7, a reflective layer 220 is formed on the cup-structures 210 by performing a process of sputtering, evaporation or chemical deposition. The reflective layer 220 can be metal or optical films that have a good reflectivity. Next, a transparent insulating layer 230 is formed on the reflective layer 200 by performing a process of sputtering, evaporation or chemical deposition. As shown in FIG. 8, then, a conductive layer 240 is formed on the transparent insulating layer 230 in each cup-structure 210 by performing a process of deposition or electroplate combined with a process of lithographic and etching process or lift off. As shown in FIG. 9, a flip chip attachment process is performed. The electrodes of a plurality of LEDs 250 are deposited with solder bumps, and then, the LEDs 250 are respectively mounted upside down on the conductive layer 240 in each cup-structure 210. Next, a solder reflow process is performed, and the LEDs 250 can be connected to the external circuits through the conductive layer 240. The LED array package structure is achieved. Besides, the connecting method of the LED 250 and the conductive layer 240 also can be die attachment using glass frit, and then, a ultrasonic wire bonding process can be used to electrically connect the electrodes of the LEDs 250 to the conductive layer 240 through the wires (not shown in figure).

In summary, the present invention provides a method to fabricate cup-structures having high density in an array on the silicon substrate by a semiconductor process or a microelectromechanic process and to dispose the LEDs in the cup-structures. Therefore, the present invention has characteristics of a high density, a high fill factor, a uniformly light pattern, a short light-mixing distance and a high illumination efficiency, and the present invention also can reduce the cost compared with the large-sized LED.

Those skilled in the art will readily observe that numerous modifications and alterations of the device and method may be made while retaining the teachings of the invention.

What is claimed is:

1. An LED package structure having a silicon substrate, comprising:
a silicon substrate having a plurality of cup-structures thereon;
a reflective layer disposed on the silicon substrate;
a transparent insulating layer disposed on the reflective layer;
a conductive layer disposed on the transparent insulating layer; and
a plurality of LEDs respectively disposed on the conductive layer in each cup-structure.

2. The LED package structure of claim 1, wherein a top view of each cup-structure is geometric.

3. The LED package structure of claim 1, wherein the cup-structures are arranged in a rectangular array.

4. The LED package structure of claim 1, wherein each cup-structure has inclined sidewalls.

5. The LED package structure of claim 1, wherein a distance between edges of the adjacent cup-structures is less than 10 μm.

6. The LED package structure of claim 1, wherein the reflective layer is metal.

7. The LED package structure of claim 1, wherein the reflective layer is optical films.

8. A method of making an LED package structure, comprising:
providing a silicon substrate, and performing an etching process to form a plurality of cup-structures on the silicon substrate;
respectively forming a reflective layer and a transparent insulating layer on the silicon substrate;
forming a conductive layer on the transparent insulating layer; and
respectively bonding a plurality of LEDs on the conductive layer in each cup-structure.

9. The method of claim 8, wherein the etching process comprises a reactive ion etching process.

10. The method of claim 8, wherein the etching process comprises a Bosch process.

11. The method of claim 8, wherein the etching process comprises a wet etching process using KOH as an etching solution.

12. The method of claim 8, wherein the etching process comprises a wet etching process using TMAH as an etching solution.

13. The method of claim 8, wherein the etching process comprises a wet etching process using EDP as an etching solution.

14. The method of claim 8, wherein the reflective layer on the silicon substrate is formed by sputtering, evaporation or chemical deposition.

15. The method of claim 8, wherein the transparent insulating layer on the silicon substrate is formed by sputtering, evaporation or chemical deposition.

16. The method of claim 8, wherein the conductive layer on the transparent insulating layer is formed by lift off.

17. The method of claim 8, wherein the conductive layer on the transparent insulating layer is formed by a lithographic and etching process.

18. The method of claim 8, wherein the LEDs on the conductive layer are bonded by flip chip attachment.

19. The method of claim 8, wherein the LEDs on the conductive layer are bonded by die attachment using glass frit.
